(19) United States
(12) Patent Application Publication
(10) Pub. No.: US 2013/0329374 A1
(43) Pub. Date: Dec. 12, 2013

(54) Pre-molded Cavity 3D Packaging Module with Layout

(71) Applicants: Keng-Hung Lin, Hsinchu County (TW); Ming-Lun Chang, Hsinchu County (TW); Yu-Min Lin, Kaohsiung City (TW)

(72) Inventors: Keng-Hung Lin, Hsinchu County (TW); Ming-Lun Chang, Hsinchu County (TW); Yu-Min Lin, Kaohsiung City (TW)

(73) Assignees: Keng-Hung Lin, Hsinchu County (TW); CMSC, Inc., Hsinchu (TW)

(21) Appl. No.: 13/542,782

(22) Filed: Jul. 6, 2012

(30) Foreign Application Priority Data
Jun. 6, 2012 (TW) 101120248

(51) Int. Cl. H05K 5/00; H05K 7/00

(52) U.S. Cl. 361/728; 174/520

(57) ABSTRACT

A pre-molded cavity 3D packaging module with layout is disclosed. The 3D packaging module includes a pre-molded cavity. A wall and a vertical plane of the pre-molded cavity form an inclined angle of more than 3°. An intersecting region between a bottom and a sidewall of the 3D packaging module has a curved profile to facilitate smooth circuit layout.

### BACKGROUND OF THE INVENTION

1. Field of the Invention

The present invention relates to a three-dimensional (3D) packaging module, and more particularly, to a pre-molded cavity 3D packaging module with layout.

2. Description of the Prior Art

Demands of low cost, small size and versatility have become the main driving forces of the electronics industry. One of the main challenges of the IC industry lies in the cost effective assembly of the various functions in a limited package, so that dies of different functions may achieve their best performances. To this end, various advanced packaging technology have been developed, such as flip-chip, chip scale packaging, wafer-level packaging and 3D packaging technology. However, in the fields of digital, analog, memory and wireless radio frequency applications, different functions of the electronic circuits will have different needs and results facing the need for miniaturization of the process technology, therefore the single-chip integration of different functions no longer provides the best solution. With the rapid developments of technologies like System-on-Chip (SOC), System-in-Package (SiP), Package-in-Package (PiP), Package-on-Package (POP) and stacked CSP, the most efficient system chip in recent years should be directed to the structure of a single package by full use of the architecture of the multi-dimensional space, wherein chips of various functions employing heterogeneous technologies and different operating voltages can be integrated. Therefore, the current trend for system chip packaging has shifted towards the concept of three-dimensional (3D) packaging technology, which is capable of integrating dies, packaged and passive components into a single package body, providing a viable solution for system packaging. The arrangement of the integration of 3D packaging technology can be side-by-side, stacked or a combination of the two. In particular, 3D packaging has the advantages such as a small footprint, high performance and low cost.

Specifically, the above System-in-Package (SiP) involves the assembly of different types of ICs in a package. Based on SiP, a new technology is extended to allow multiple pieces of dies to be stacked in a package module, and achieve the integration of more features or a higher density with the use of three-dimensional space. Among these types of package structures, stacked CSP was the first to be released; its products are mostly memory combo and it is capable of stacking six layers of memory dies in a ball grid array (BGA) package. In addition to the traditional wire bonding, solder bumps or flip-chip technology can also be used. In addition, interposers are often added in order to facilitate stacking or heat dissipation. For example, a package with stacked dies may include dies that are separate but connected with each other through wires (die as building blocks); may include a stacking of one to several pieces of memory dies, an analog die stacked on top of another system-on-Chip (SOC) or digital die, while an independent radio frequency (RF) die disposed on an interconnected substrate. These constituent dies all have different control and I/O (Input/Output) paths.

Referring to FIGS. 1A to 1D, a traditional stacked package structure typically includes a plurality of substrate, a plurality of packaged chipsets and solder balls; some of the packaged chipsets are adhered or bonded on a top surface of a substrate and are electrically connected by pins or solder balls, while some of the packaged chipsets are adhered or bonded on top and/or bottom surfaces of another substrate and are electrically connected by pins or solder balls. The two substrates are connected together with rigid conductors or solder balls in order to facilitate stacking in a three-dimensional space and the formation of 3D packaging architecture, wherein substrates, printed circuit boards (PCBs), and leadframes are connected through solder balls, connection columns, ring-shaped substrates or PCBs with opening therein and curved feet forming as interposers to provide the required space for connection. The interposers in a traditional 3D package or module provide connections for the upper and lower layers through pins having circuit functions.

Packaging currently adopted by most packaging factories are like those shown in the diagrams just described, which is a multi-layer stacked package structure involving mainly packaged dies. However, this type of multi-layer stacked package is faced with several challenges. In one aspect, if chips and wires are directly exposed to the air without protection, this will lead to reliability problems. Therefore, the circuits of the chips cannot be connected onto the holder using wire bonding process, and the components used in these package structures must be packaged components and are soldered onto the holder or PCB in an exposed and unprotected way. Although coating a protective layer may provide re-packaging protection, but once the protective layer is coated, if an internal component is defective or damaged, unless this protective layer is removed, the whole packaging module will have to be discarded, dismantling of components for repair is not possible. For packaging factories, the cost of repair is high. In another aspect, no immediate testing can be performed on traditional 3D packages at the time of manufacturing but only after the packaging, mass production is hindered.

Moreover, in a traditional multi-layer stacked package structure, if a rigid conductor is used for shelf support, despite that the interlayer height can be controlled, alignment control during the manufacturing process is very difficult. On the contrary, if solder balls are used for the shelf support, alignment issue can be easily solved, but there are height restrictions, such that the lower components are more easily pressed by the upper substrates. In addition, the traditional 3D structure is famous for its heat dissipation problem, more layers mean more system modules that are in operation, and the heat generated by each component will produce a synergistic effect. As a result, the multi-layer stacked package structure has very poor cooling effect. Furthermore, each individual packaged component has their own stamp, but for the entire packaging module, the stamp is made on the holder or the PCB, and no packaging date for the module is available for retrospective purpose.

All these factors will seriously affect the reliability of 3D packaging, and greatly reduce the yield of the packaging process, resulting in a substantial increase in cost. Therefore, how to overcome these shortcomings is still the major target of the industry requiring much-needed development.

### SUMMARY OF THE INVENTION

In view of the above and in accordance with the needs of the industry, the present invention proposes a pre-molded cavity 3D packaging module with layout to address the issues encountered in the prior art.

One objective of the present invention is to provide pre-molded cavity 3D packaging module with layout. The 3D packaging module provided protection, and packaged or unpackaged components can be protected within the 3D packaging module. In addition, the outside of the 3D packaging module provides a flat area for laser or ink stamping to enable easy tracing of the packaging date of the overall module. Moreover, the structure of the present invention may provide solder pads or balls as output electrodes, and testing pads are pre-manufactured by bottom through-hole drilling for internal component testing during production, this increases the viability of mass-production. On the other hand, the 3D packaging module structure of the present invention is composed of a pre-molded holder or cavity and is assembled into a 3D package or module structure. In this 3D package or module structure, chips and wires are not directly exposed, and packaged components, passive components and chips are soldered onto the pre-molded cavity holder, and the substrate or PCB on which the packaged or passive components are soldered can also be used as a lid or an internal circuit layer of the 3D packaging module of the present invention.

The circuit connection for the 3D packaging module of the present invention involves forming circuits from the bottom through the sidewall to the upper-layer substrate and the lid. The upper-layer substrate of the 3D packaging module of the present invention can be connected to the circuits on the sidewall of the pre-molded cavity through conductive materials. The 3D packaging module of the present invention can be a massive module with small footprint by stacking pre-molded cavity, sub-modules and PCBs into a 3D structure. The various substrates in the 3D packaging module of the present invention can be designed to accommodate the needs of other modules or circuit area requirements, and are not limited to the dimensions of the 3D packaging module of the present invention. The area of the circuit layout can be extended by substrates or PCBs, which can be attached within the 3D packaging module of the present invention by conductive materials. The circuit layout of the 3D packaging module of the present invention reduces the length of solder wires.

The concept of the 3D packaging module of the present invention can be extended to a 3D packaging structure with multiple modules. The 3D packaging module of the present invention is composed of a pre-molded cavity. A wall and a vertical plane of the pre-molded cavity form an inclined angle of more than 3°. An intersecting region between a bottom and a sidewall of the 3D packaging module has a curved profile to facilitate smooth circuit layout. The circuit connections of the 3D packaging module of the present invention can be made in the form of steps on the sidewall, and are not restricted to two dimensions. With the 3D packaging module of the present invention, staggered wire layouts on different vertical planes can prevent short circuit caused by mold flow. The circuits of the 3D packaging module of the present invention can be manufactured on the planar bottom of the pre-molded cavity, and connected with output solder pads through vias. The output solder pads can be flexibly manufactured to connect to the bottom of the cavity holder through vias, or as solder balls/pads on an upper-lid PCB.

Accordingly, with the pre-molded cavity 3D packaging module with layout of the present invention, not only the numerous shortcomings of the prior art are addressed, flexible design is also made possible. Therefore, the present invention can be widely used in the commerce and industry of the packaging modules, achieving a major target of the industry that required much-needed development.

According to the objectives of the present invention, a pre-molded cavity three-dimensional (3D) packaging module with layout is provided by the present invention. The pre-molded cavity 3D packaging module with layout includes: a first circuit with at least a specific layout; and at least one packaging cavity with the first circuit on a cavity surface thereof, and forming a receiving space by a cavity bottom and a cavity sidewall surrounding the cavity sidewall, wherein the cavity sidewall forms an inclined angle greater than 3° with a vertical axis of the cavity bottom, and the receiving space is for receiving at least one component to be electrically coupled with the first circuit. In addition, an intersecting region between the cavity sidewall and the cavity bottom is a curved intersecting region for forming a circuit with at least a specific layout thereon, and the cavity bottom at the curved intersecting region forms steps of different heights to facilitate staggered wire layouts or wire bonding on different vertical planes. Moreover, the at least one packaging cavity includes at least one via through which the first circuit is electrically coupled to external circuits, and the outer surface of the at least one packaging cavity includes at least one signal transmitting region, which transmits incoming/outgoing signals to/from the first circuit through the first via, wherein the at least one signal transmitting region is a module testing region.

The at least one packaging cavity above includes at least one heat-dissipating path, wherein the at least one heat-dissipating path has at least one heat-dissipating area exposed from the outer surface of the packaging cavity, and the at least one packaging cavity includes at least one air hole for exchanging air with an external environment to form an air-type packaging module, wherein a material is filled into the air hole to block the air hole, and during assembly of the packaging cavity, inert gas is filled into it, or it is heated to remove moisture to form a sealed packaging module. Moreover, the pre-molded cavity 3D packaging module with layout above further includes at least one first cavity holder with a length greater than the width of the opening of the at least one packaging cavity. Furthermore, the first cavity holder includes a second circuit with at least a specific layout and at least one second via, the second circuit is formed on a surface of the first cavity holder, and at least one signal transmitting region is formed on the other surface of the first cavity holder for transmitting signals to/from the second circuit through the second via, and the cavity sidewall has at least one step forming a staircase-like surface with at least one ledge in the receiving space.

The pre-molded cavity 3D packaging module with layout above further includes at least one second cavity holder received on the ledge, and the second cavity holder further includes a third circuit with at least a specific layout and at least one third via, the third circuit is formed on a surface of the second cavity holder, and an electrical coupling region is formed on the other surface of the second cavity holder through the at least one third via, wherein the receiving space of the at least one packaging cavity is filled with a liquid material with low stress for protecting internal components and solder wires. In addition, the pre-molded cavity 3D packaging module with layout above further includes a U-shaped packaging cavity, a symmetric packaging cavity, and an H-shaped packaging cavity, wherein the type of the pre-molded cavity 3D packaging module with layout is selected from one or a combination of the above. The H-shaped packaging cavity includes two opposite openings and two cavity holders, and the symmetric packaging cavity includes a pair of symmetric packaging cavities.

According to the objectives of the present invention, a pre-molded cavity three-dimensional (3D) packaging module with layout is provided, which includes a packaging module with a plurality of packaging cavities, each cavity forming a receiving space by a cavity bottom and a cavity sidewall surrounding the cavity sidewall for receiving at least one component, wherein the cavity sidewall forms an inclined angle greater than 3° with a vertical axis of the cavity bottom, and an intersecting region between the cavity sidewall and the cavity bottom is a curved intersecting region to facilitate the formation of a circuit with at least a specific layout; a first circuit with at least a specific layout formed on the surface of the cavity sidewall and over the cavity sidewall to electrically couple the component in each packaging cavity; and at least a cavity holder for packaging each packaging cavity, wherein the cavity bottom at the curved intersecting region forms steps of different heights to facilitate staggered wire layouts or wire bonding on different vertical planes. The above packaging module includes at least one via through which the first circuit is electrically coupled to external circuits, and the outer surface of a packaging module includes at least one signal transmitting region, which transmits incoming/outgoing signals to/from the first circuit through the first via.

The at least one signal transmitting region above is at least one module testing region, and the above packaging module includes at least one heat-dissipating path, wherein the at least one heat-dissipating path has at least one heat-dissipating area exposed from the outer surface of a packaging cavity. In addition, the packaging module includes at least one air hole for exchanging air with an external environment to form an air-type packaging module, wherein a material is filled into the air hole to block the air hole, and during assembly of the packaging module, inert gas is filled into it, or it is heated to remove moisture to form a sealed packaging module. The above cavity holder further includes a second circuit with at least a specific layout and at least one second via, the second circuit is formed on a surface of the cavity holder, and an electrical coupling region is formed on the other surface of the cavity holder through the second via, wherein the cavity sidewall has at least one step forming a staircase-like surface with at least one ledge in the receiving space. Moreover, the receiving space is filled with a liquid material with low stress for protecting internal components and solder wires. The plurality of packaging cavities above include the cavity bottoms of different thickness.

According to the objectives of the present invention, a pre-molded cavity three-dimensional (3D) packaging module with layout is provided, which includes: a packaging cavity forming a receiving space by a cavity bottom and a cavity sidewall surrounding the cavity sidewall, wherein the cavity sidewall forms an inclined angle greater than 3° with a vertical axis of the cavity bottom, and an intersecting region between the cavity sidewall and the cavity bottom is a curved intersecting region, and the cavity sidewall has a plurality of steps forming staircase-like surfaces with a plurality of ledges in the receiving space; a plurality of first circuits with specific layouts formed on a surface of the packaging cavity in the receiving space and on the curved intersecting region, wherein the first circuits are each electrically coupled with a component received in the receiving space; and a plurality of packaging holder disposed on the plurality of ledges, each packaging holder having a component on a surface thereof. The cavity bottom at the curved intersecting region forms steps of different heights to facilitate staggered wire layouts or wire bonding on different vertical planes. The above packaging cavity includes a plurality of first vias through which the first circuits are electrically coupled to external circuits. The outer surface of the above packaging cavity includes a plurality of signal transmitting regions, which transmit incoming/outgoing signals to/from the first circuits through the first vias. The signal transmitting regions above are module testing regions. The plurality of packaging holders above include a plurality of second vias and second circuits with specific layouts, the second circuits are formed on surfaces of the plurality of packaging holders, and electrically coupled with components on both surfaces of the packaging holders through the plurality of second vias. The above packaging cavity includes at least one heat-dissipating path, wherein the at least one heat-dissipating path has at least one heat-dissipating area exposed from the outer surface of the packaging cavity. The above packaging cavity includes at least one air hole for exchanging air with an external environment to form an air-type packaging module, wherein a material is filled into the air hole to block the air hole, and during assembly of the packaging cavity, inert gas is filled into it, or it is heated to remove moisture to form a sealed packaging module. The receiving space of the above packaging cavity is filled with a liquid material with low stress for protecting internal components and solder wires.

According to the objectives of the present invention, a pre-molded cavity three-dimensional (3D) packaging module with layout is provided, which includes: a plurality of packaging cavities, each forming a receiving space by a cavity bottom and a cavity sidewall surrounding the cavity sidewall, wherein the cavity sidewall forms an inclined angle greater than 3° with a vertical axis of the cavity bottom, and an intersecting region between the cavity sidewall and the cavity bottom is a curved intersecting region; the plurality of packaging cavities further including a first packaging cavity, a second packaging cavity, a third packaging cavity, and a fourth packaging cavity, wherein the second packaging cavity and the third packaging cavity are matching in appearance and symmetrical with each other, and with opening larger than the cavity sidewall of the first packaging cavity to be assembled to the cavity sidewall, and the cavity sidewall of the first packaging cavity has a plurality of steps forming staircase-like surface with a plurality of ledges in the receiving space; a plurality of first circuits with specific layouts formed on a surface of a packaging cavity in the receiving space and on the curved intersecting region, wherein the first circuits are each electrically coupled with a component received in the receiving space; and a plurality of packaging holder disposed on the plurality of ledges, each packaging holder having a component on a surface thereof.

The above cavity bottom at the curved intersecting region forms steps of different heights to facilitate staggered wire layouts or wire bonding on different vertical planes, and the plurality of packaging cavities above include a plurality of first vias through which the first circuits are electrically coupled to external circuits, wherein the outer surfaces of the plurality of packaging cavities include a plurality of signal transmitting regions, which transmit incoming/outgoing signals to/from the first circuits through the first vias, and the signal transmitting regions are module testing regions. In addition, the plurality of packaging holders above include a plurality of second vias and second circuits with specific layouts, the second circuits are formed on surfaces of the plurality of packaging holders, and electrically coupled with components on both surfaces of the packaging holders through the plurality of second vias, and the packaging cavities each includes at least one heat-dissipating path, wherein the at least one heat-dissipating path has at least one heat-dissipating area exposed from the outer surface of the packaging cavity. Moreover, the packaging cavities above each includes at least one air hole for exchanging air with an external environment to form an air-type packaging module, wherein a material is filled into the air hole to block the air hole, and during assembly of the packaging cavity, inert gas is filled into it, or it is heated to remove moisture to form a sealed packaging module, wherein the receiving space of each packaging cavity is filled with a liquid material with low stress for protecting internal components and solder wires.

### BRIEF DESCRIPTION OF THE DRAWINGS

The present invention can be more fully understood by reading the following detailed description of the preferred embodiments, with reference made to the accompanying drawings, wherein:

FIGS. 1A to 1D are schematic diagrams illustrating prior-art packaging designs;

FIGS. 2A to 2L are schematic diagrams illustrating a pre-molded cavity 3D packaging module with layout according to embodiments of the present invention; and

FIGS. 3A to 3D are black and white photos of the actual implementations of the pre-molded cavity 3D packaging module with layout according to embodiments of the present invention.

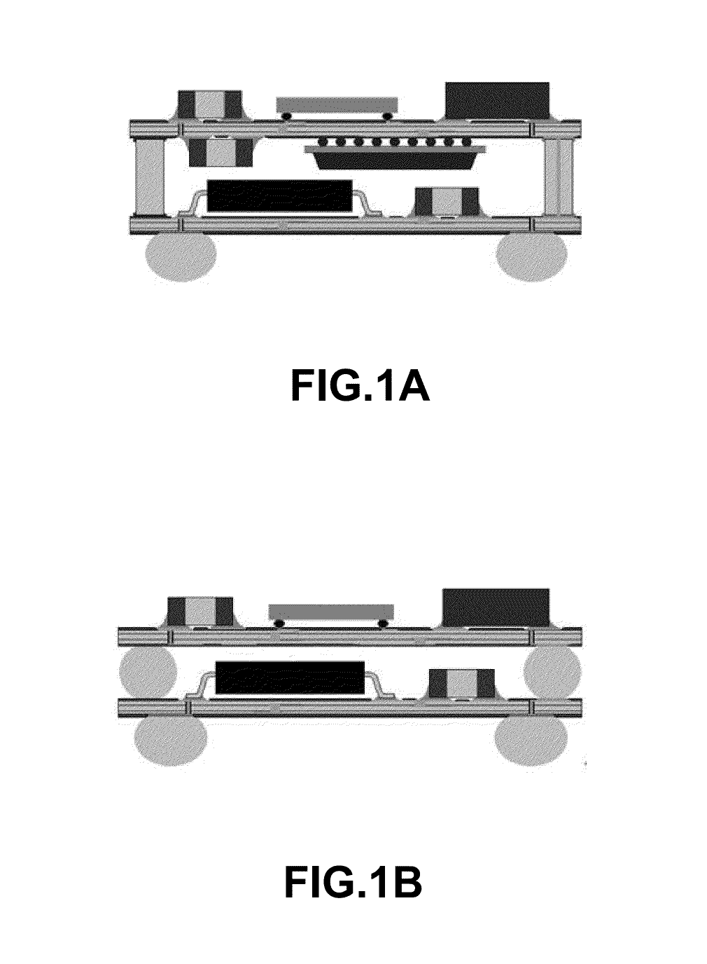

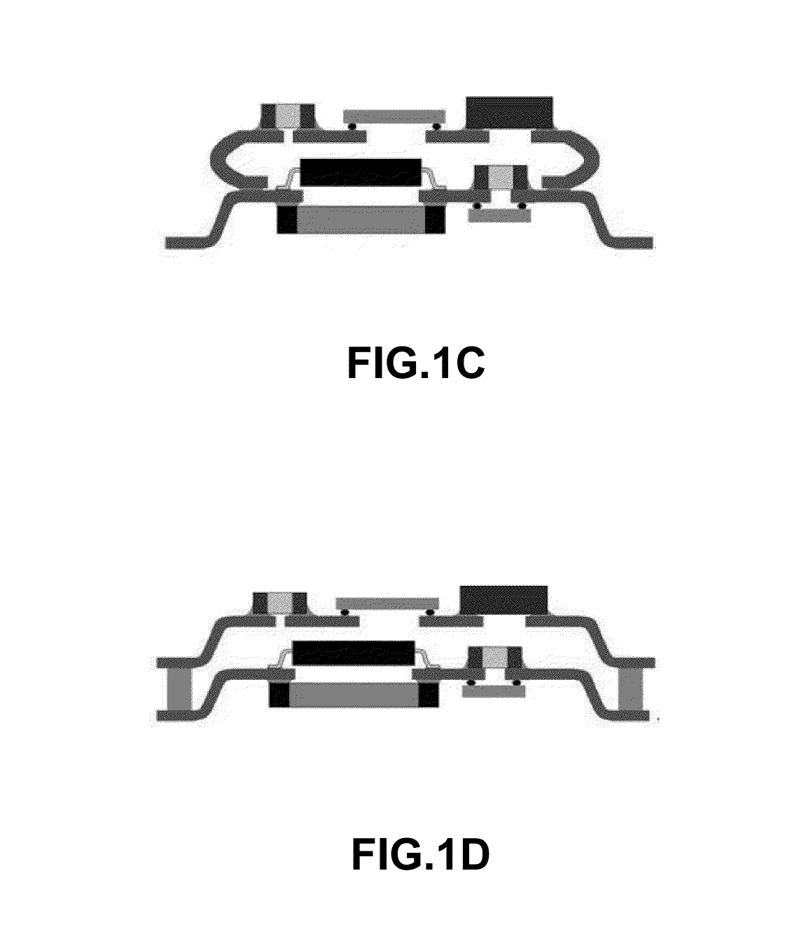

### DETAILED DESCRIPTION OF THE PREFERRED EMBODIMENTS

The present invention is directed to three-dimensional (3D) packaging modules. In order to facilitate understanding of the present invention, detailed structures and their elements and method steps are set forth in the following descriptions. Obviously, the implementations of the present invention are not limited to specific details known to those skilled in the art of packaging module. On the other hand, well-known structures and their elements are omitted herein to avoid unnecessary limitations on the present invention. In addition, for better understanding and clarity of the description by those skilled in the art, some components in the drawings may not necessary be drawn to scale, in which some may be exaggerated relative to others, and irrelevant parts are omitted. Preferred embodiments of the present invention are described in details below, in addition to these descriptions, the present invention can be widely applicable to other embodiments, and the scope of the present invention is not limited by such, rather by the scope of the following claims.

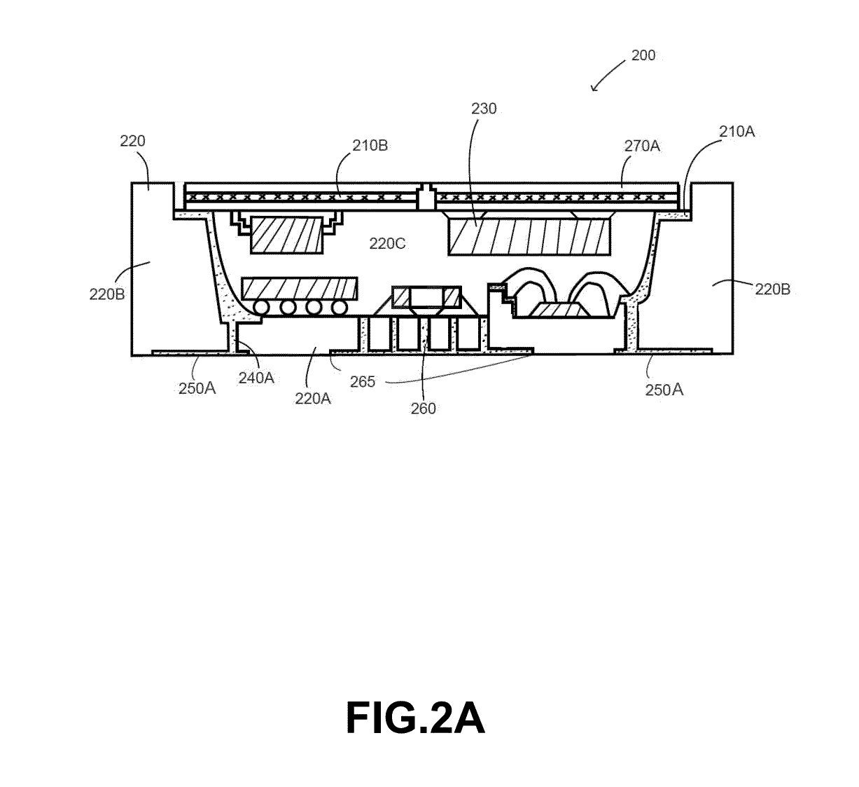

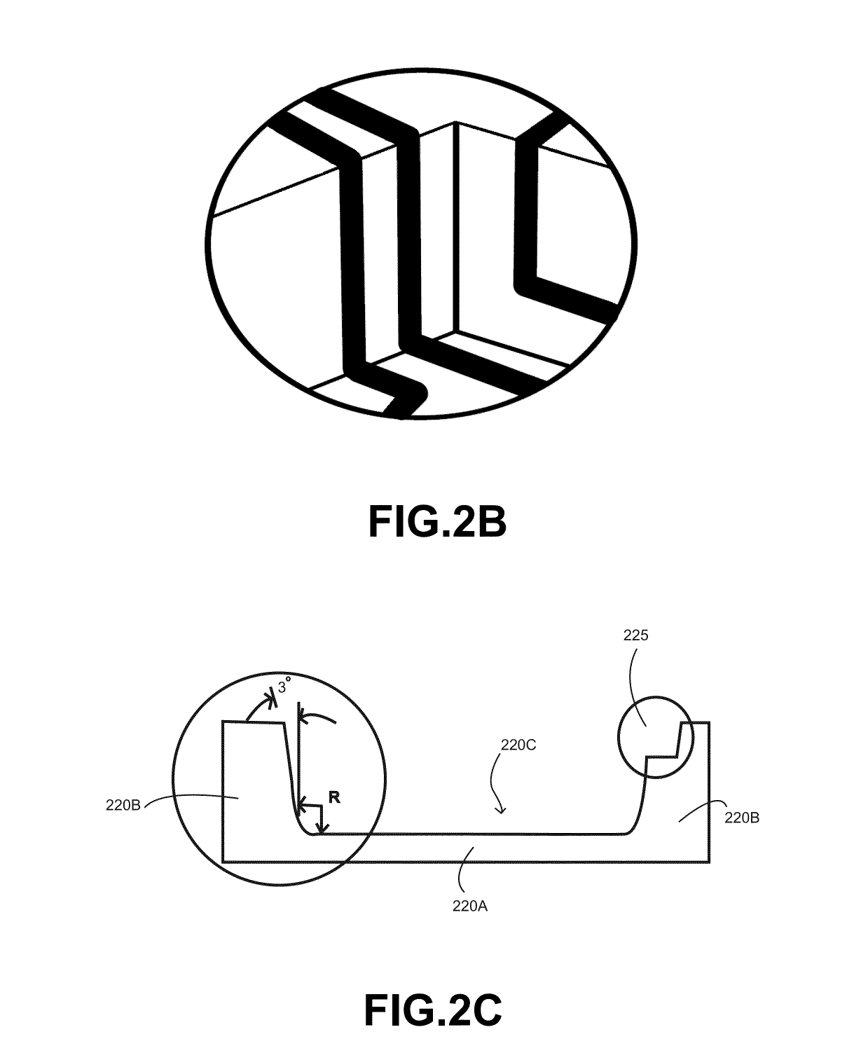

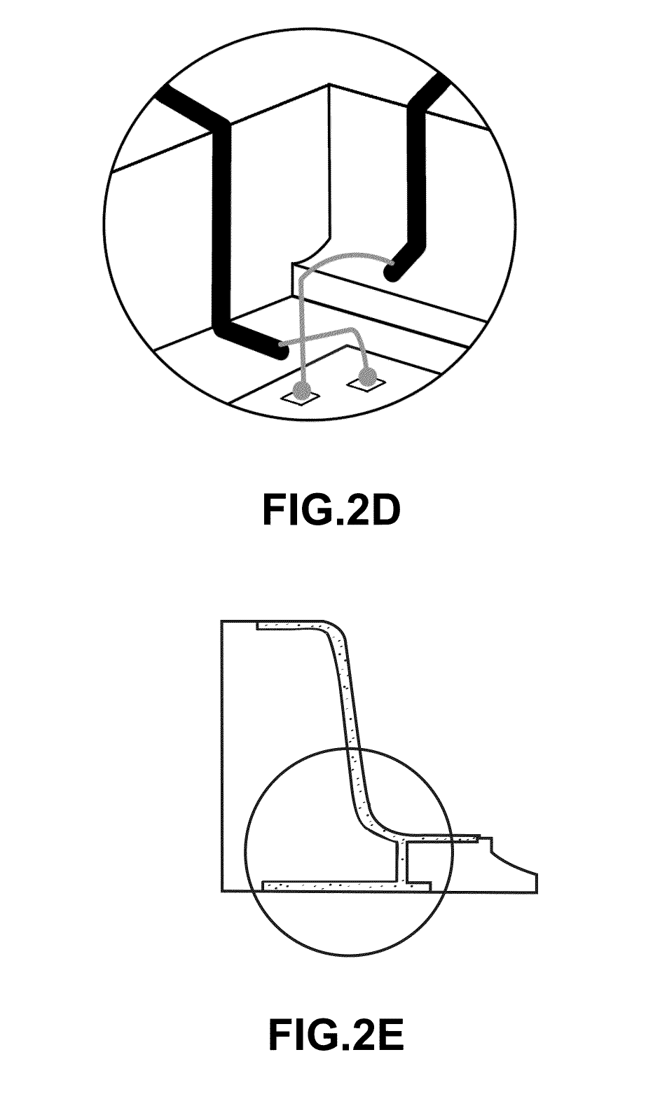

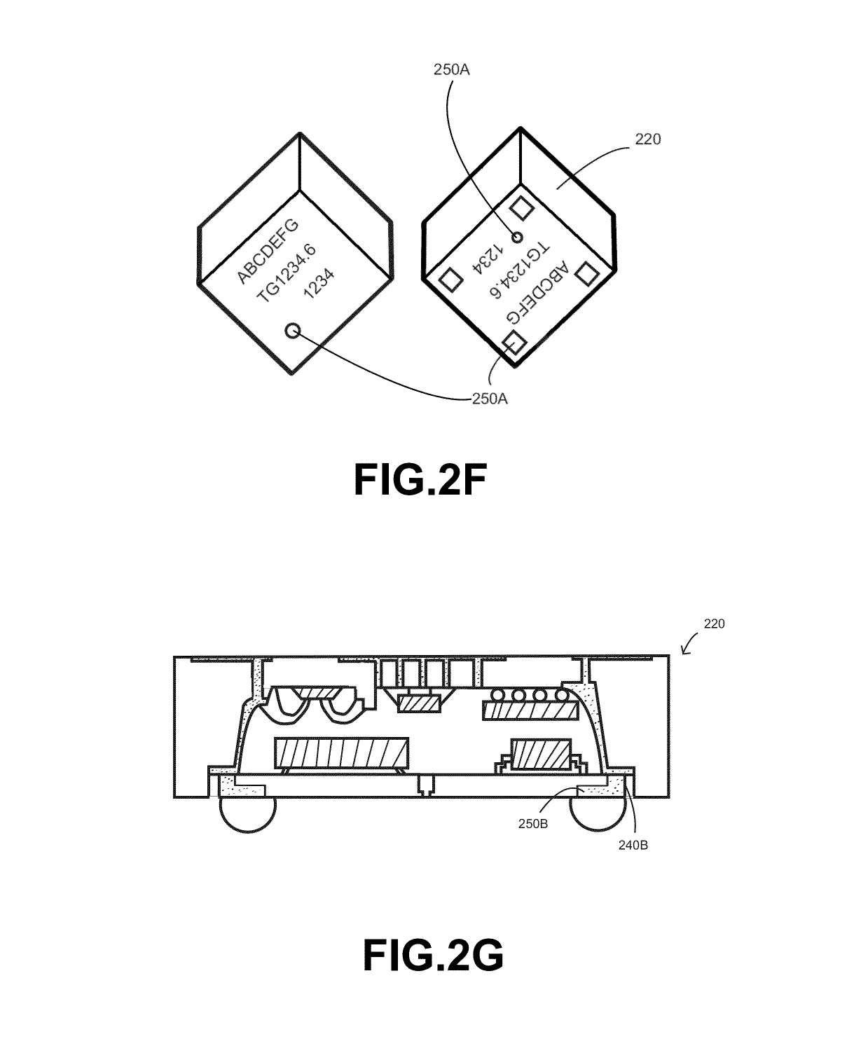

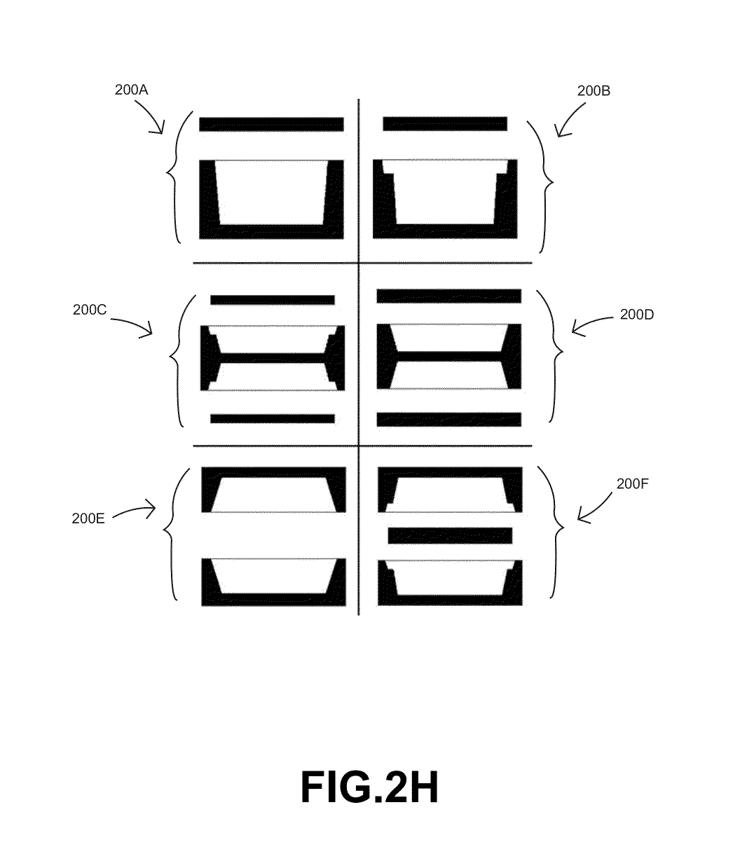

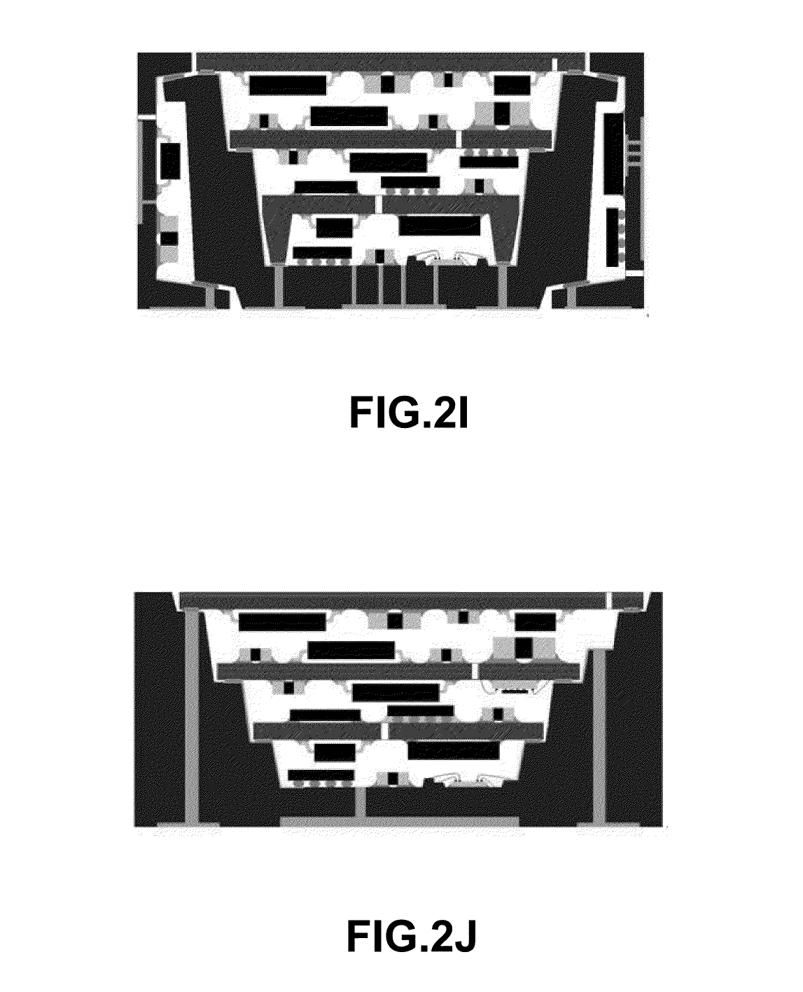

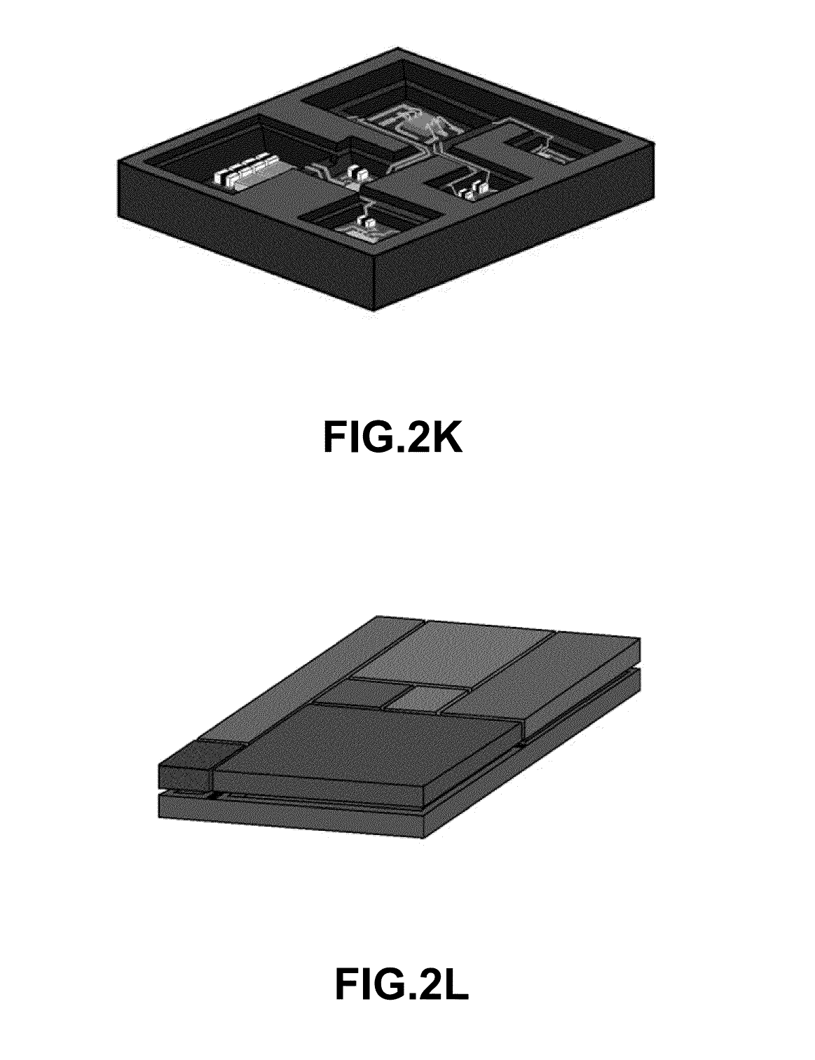

According to an embodiment of the present invention, referring to FIG. 2A, a pre-molded cavity 3D packaging module with layout 200. The pre-molded cavity 3D packaging module with layout includes a first circuit 210A with at least a specific layout and at least one packaging cavity 220. The at least one packaging cavity 220 forms a receiving space 220C with a cavity bottom 220A and a cavity sidewall 220B surrounding the cavity bottom 220A, wherein the first circuit 210A is pre-formed on the surfaces of the packaging cavity 220 including the cavity bottom 220A and the cavity sidewall 220B, as shown in FIG. 2B. The receiving space 220C can receive at least one component 230 to be electrically coupled with the first circuit 210A, wherein if the component 230 is a packaged component, then it can be electrically coupled with the first circuit 210A using pins or solder balls at specific locations. If the component 230 is not a packaged component, then it can be electrically coupled with the first circuit 210A directly using wiring bonding technique at specific locations.

Referring to FIG. 2C, according to an embodiment of the present invention, the cavity sidewall 220B forms an inclined angle larger than 3° with an vertical axis of the cavity bottom 220A, and the intersecting region between the cavity sidewall 220B and the cavity bottom 220A is a curved intersecting region R in order to facilitate the first circuit 210A to be smoothly formed from the cavity bottom 220A through the curved intersecting region R onto the cavity sidewall 220B, wherein the bottom of the cavity sidewall 220B at the curved intersecting region R are formed with steps of different heights, so as to facilitate staggered wire layouts or wire bonding on different vertical planes, as shown in FIG. 2D. The at least one packaging cavity 220 further includes at least a first via 240A to allow the first circuit 210A to be electrically coupled with external circuits through the first via 240A. In addition, the outer surface of the at least one packaging cavity 220 includes at least a first signal transmitting region 250A. The first signal transmitting region 250A is electrically coupled to the first circuit 210A through the first via 240A to transmit incoming/outgoing signals, as shown in FIG. 2E, wherein the first signal transmitting region 250A can be testing electrodes for a module testing area and/or I/O electrodes. The outer surface of the packaging cavity 220 is available for stamps of packaging date or other information, as shown in FIG. 2F.

Referring to FIG. 2A, according to an embodiment of the present invention, the at least one packaging cavity 220 further includes at least one heat-dissipating path 260 for dissipating heat, wherein the at least one heat-dissipating path 260 may have at least one heat-dissipating area 265 exposed from the outer surface of the packaging cavity. The at least one packaging cavity 220 further includes at least one air hole for exchanging air with the external environment, thereby forming an air-type packaging module, wherein a material can be used to block the air hole, and during adhesion of the overall cavity, inert gas is filled into it, or it is heated to remove moisture, thereby forming a sealed packaging module. In addition, the pre-molded cavity 3D packaging module with layout further includes at least a first cavity holder 270A. The length of the first cavity holder 270A is greater than the width of the opening of the at least one packaging cavity 220. The first cavity holder 270A includes a second circuit 210B with at least a specific layout and at least one second via 240B. The second circuit 210B is formed on a surface of the first cavity holder 270A, and at least a second signal transmitting region 250B is formed on the other surface of the first cavity holder 270A for transmitting signals to/from the second circuit 210B through the at least one second via 240B, as shown in FIG. 2G, wherein the second signal transmitting region 250B can be adhered with conductive objects such as solder bumps/balls. Moreover, the cavity sidewall 220B includes at least one step, forming a staircase-like surface with at least one ledge 225 in the receiving space 220C, as shown in FIG. 2C. The at least one first cavity holder 270A can be placed on the ledge 225 to seal the receiving space 220C. In addition, the receiving space 220C of the at least one packaging cavity 220 can be filled with a liquid material with low stress to protect the internal components and solder wires.

Referring to FIG. 2H, according to an embodiment of the present invention, the pre-molded cavity 3D packaging module with layout 200 further includes U-shaped packaging cavities 200A/200B, symmetric packaging cavities 200E/200F, and H-shaped packaging cavities 200C/200D, wherein the type of the pre-molded cavity 3D packaging module with layout 200 can be selected from one or a combination of the above. Furthermore, the H-shaped packaging cavities 200C/200D each includes two opposite openings and two cavity holders. The symmetric packaging cavities 200E/200F each includes a pair of symmetric packaging cavities. As described above, the assembly of the present invention is based on the concept of 3D spatial stacking, similar to the stacking of toy bricks, which is different from the traditional vertical stacking. For example, different cavity combinations can be used depending on the needs, such as, 200B/200C/200B, 200A/200C/200A . . . etc. An exemplary combinational stacking is shown in FIG. 2I. Referring further to FIG. 2J, a modification of the present embodiment is shown, wherein there are several ledges on a cavity sidewall of a packaging cavity, and cavity holders with appropriate sizes are placed on these ledges.

According to an embodiment of the present invention,

According to an embodiment of the present invention, the cavity holder of the 3D package or module of the present invention can be used directly as a PCB or PVB, so not only the internal substrates or PCBs can be used for extension, a plurality of cavity substrates for different modules can be soldered onto a fundamental module substrate for extension, as shown in FIG. 2K. FIG. 2K shows a plurality of packaging cavities with different thicknesses in the same packaging module, cavities can be interconnected through circuits going over the cavity sidewalls, thus, package miniaturization can be easily achieved, wherein each packaging cavity is provided with an appropriate cavity holder to complete the packaging, as shown in FIG. 2L. Alternatively, a single cavity holder can be used for packaging the plurality of cavities.

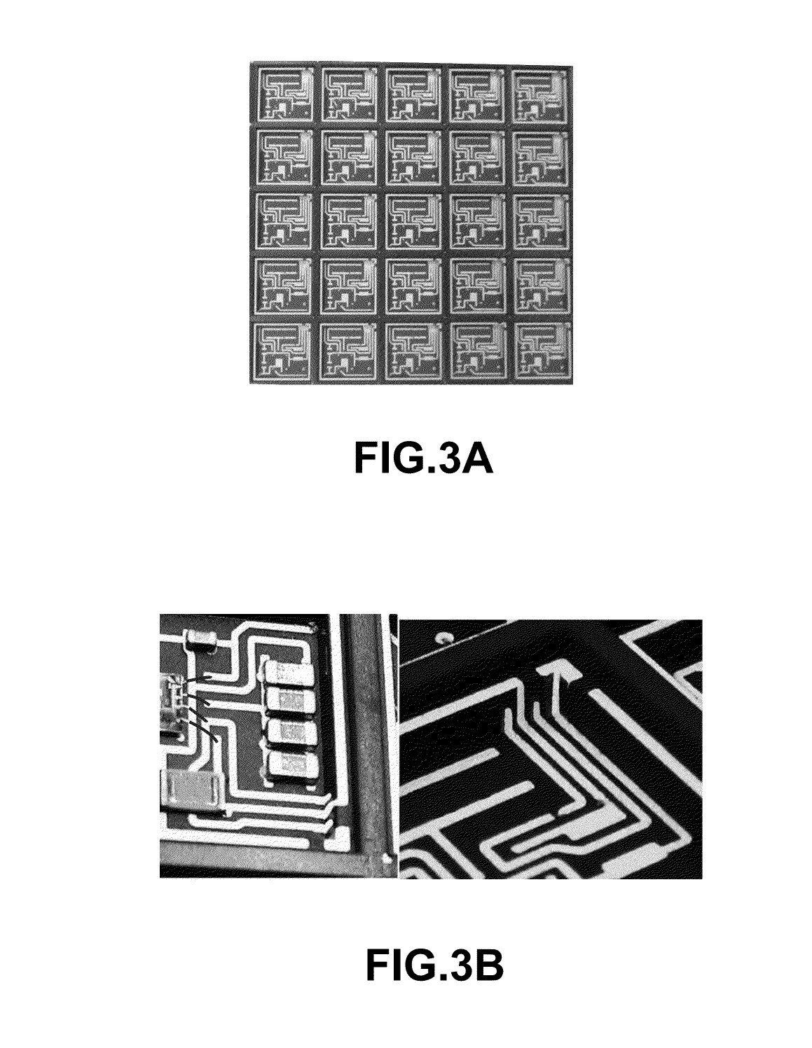

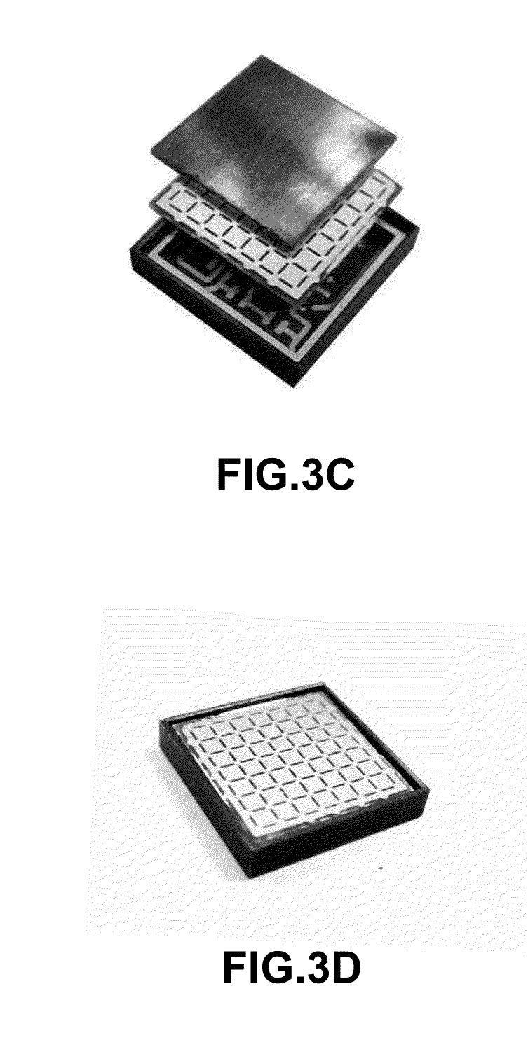

According to an embodiment of the present invention, black and white photos of the actual implementations of the present invention are shown in FIGS. 3A to 3D, in which circuit layouts can be designed on the sidewalls of the packaging module. The circuits can be connected by going over the sidewalls and thus are not limited to a planar design. Moreover, the present invention also allows unpackaged components to be directly wire-bonded in the packaging module. It is apparent that based on the above descriptions of the embodiments, the present invention can have numerous modifications and alterations, and they should be construed within the scope of the following claims. In addition to the above detailed descriptions, the present invention can be widely applied to other embodiments. The above embodiments are merely preferred embodiments of the present invention, and should not be used to limit the present invention in any way. Equivalent modifications or changes can be made by those with ordinary skill in the art without departing from the scope of the present invention as defined in the following appended claims.

What is claimed is:

1. A pre-molded cavity three-dimensional (3D) packaging module with layout, comprising:
a first circuit with at least a specific layout; and
at least one packaging cavity with the first circuit on a cavity surface thereof, and forming a receiving space by a cavity bottom and a cavity sidewall surrounding the cavity sidewall, wherein the cavity sidewall forms an inclined angle greater than 3° with a vertical axis of the cavity bottom, and the receiving space is for receiving at least one component to be electrically coupled with the first circuit.

2. The pre-molded cavity 3D packaging module with layout of claim 1, wherein an intersecting region between the cavity sidewall and the cavity bottom is a curved intersecting region to facilitate the first circuit to form smoothly from the cavity bottom through the curved intersecting region onto the cavity sidewall.

3. The pre-molded cavity 3D packaging module with layout of claim 2, wherein the cavity bottom at the curved intersecting region forms steps of different heights to facilitate staggered wire layouts or wire bonding on different vertical planes.

4. The pre-molded cavity 3D packaging module with layout of claim 1, wherein the at least one packaging cavity includes at least one via through which the first circuit is electrically coupled to external circuits.

5. The pre-molded cavity 3D packaging module with layout of claim 4, wherein the outer surface of the at least one packaging cavity includes at least one signal transmitting region, which transmits incoming/outgoing signals to/from the first circuit through the first via.

6. The pre-molded cavity 3D packaging module with layout of claim 5, wherein the at least one signal transmitting region is a module testing region.

7. The pre-molded cavity 3D packaging module with layout of claim 1, wherein the at least one packaging cavity includes at least one heat-dissipating path, wherein the at least one heat-dissipating path has at least one heat-dissipating area exposed from the outer surface of the packaging cavity.

8. The pre-molded cavity 3D packaging module with layout of claim 1, wherein the at least one packaging cavity includes at least one air hole for exchanging air with an external environment to form an air-type packaging module, wherein a material is filled into the air hole to block the air hole, and during assembly of the packaging cavity, inert gas is filled into it, or it is heated to remove moisture to form a sealed packaging module.

9. The pre-molded cavity 3D packaging module with layout of claim 1, further comprising at least one first cavity holder with a length greater than the width of the opening of the at least one packaging cavity.

10. The pre-molded cavity 3D packaging module with layout of claim 9, wherein the first cavity holder includes a second circuit with at least a specific layout and at least one second via, the second circuit is formed on a surface of the first cavity holder, and at least one signal transmitting region is formed on the other surface of the first cavity holder for transmitting signals to/from the second circuit through the second via.

11. The pre-molded cavity 3D packaging module with layout of claim 1, wherein the cavity sidewall has at least one step forming a staircase-like surface with at least one ledge in the receiving space.

12. The pre-molded cavity 3D packaging module with layout of claim 11, further comprising at least one second cavity holder received on the ledge.

13. The pre-molded cavity 3D packaging module with layout of claim 12, wherein the second cavity holder further includes a third circuit with at least a specific layout and at least one third via, the third circuit is formed on a surface of the second cavity holder, and an electrical coupling region is formed on the other surface of the second cavity holder through the at least one third via.

14. The pre-molded cavity 3D packaging module with layout of claim 1, wherein the receiving space of the at least one packaging cavity is filled with a liquid material with low stress for protecting internal components and solder wires.

15. The pre-molded cavity 3D packaging module with layout of claim 1, further comprising a U-shaped packaging cavity, a symmetric packaging cavity, and an H-shaped packaging cavity, wherein the type of the pre-molded cavity 3D packaging module with layout is selected from one or a combination of the above.

16. The pre-molded cavity 3D packaging module with layout of claim 15, wherein the H-shaped packaging cavity includes two opposite openings and two cavity holders.

17. The pre-molded cavity 3D packaging module with layout of claim 15, wherein the symmetric packaging cavity includes a pair of symmetric packaging cavities.

18. A pre-molded cavity three-dimensional (3D) packaging module with layout, comprising:
a packaging module with a plurality of packaging cavities, each cavity forming a receiving space by a cavity bottom and a cavity sidewall surrounding the cavity sidewall for receiving at least one component, wherein the cavity sidewall forms an inclined angle greater than 3° with a vertical axis of the cavity bottom, and an intersecting region between the cavity sidewall and the cavity bottom is a curved intersecting region to facilitate the formation of a circuit with at least a specific layout;
a first circuit with at least a specific layout formed on the surface of the cavity sidewall and over the cavity sidewall to electrically couple the component in each packaging cavity; and
at least a cavity holder for packaging each packaging cavity.

19. The pre-molded cavity 3D packaging module with layout of claim 18, wherein the cavity bottom at the curved intersecting region forms steps of different heights to facilitate staggered wire layouts or wire bonding on different vertical planes.

20. The pre-molded cavity 3D packaging module with layout of claim 18, wherein the packaging module includes at least one via through which the first circuit is electrically coupled to external circuits.

21. The pre-molded cavity 3D packaging module with layout of claim 20, wherein the outer surface of a packaging module includes at least one signal transmitting region, which transmits incoming/outgoing signals to/from the first circuit through the first via.

22. The pre-molded cavity 3D packaging module with layout of claim 21, wherein the at least one signal transmitting region is at least one module testing region.

23. The pre-molded cavity 3D packaging module with layout of claim 18, wherein the packaging module includes at least one heat-dissipating path, wherein the at least one heat-dissipating path has at least one heat-dissipating area exposed from the outer surface of a packaging cavity.

24. The pre-molded cavity 3D packaging module with layout of claim 18, wherein the packaging module includes at least one air hole for exchanging air with an external environment to form an air-type packaging module, wherein a material is filled into the air hole to block the air hole, and during assembly of the packaging module, inert gas is filled into it, or it is heated to remove moisture to form a sealed packaging module.

25. The pre-molded cavity 3D packaging module with layout of claim 18, wherein the cavity holder further includes a second circuit with at least a specific layout and at least one second via, the second circuit is formed on a surface of the cavity holder, and an electrical coupling region is formed on the other surface of the cavity holder through the second via.

26. The pre-molded cavity 3D packaging module with layout of claim 18, wherein the cavity sidewall has at least one step forming a staircase-like surface with at least one ledge in the receiving space.

27. The pre-molded cavity 3D packaging module with layout of claim 18, wherein the receiving space is filled with a liquid material with low stress for protecting internal components and solder wires.

28. The pre-molded cavity 3D packaging module with layout of claim 18, wherein the plurality of packaging cavities include the cavity bottoms of different thickness.

29. A pre-molded cavity three-dimensional (3D) packaging module with layout, comprising:
a packaging cavity forming a receiving space by a cavity bottom and a cavity sidewall surrounding the cavity sidewall, wherein the cavity sidewall forms an inclined angle greater than 3° with a vertical axis of the cavity bottom, and an intersecting region between the cavity sidewall and the cavity bottom is a curved intersecting region, and the cavity sidewall has a plurality of steps forming staircase-like surfaces with a plurality of ledges in the receiving space;
a plurality of first circuits with specific layouts formed on a surface of the packaging cavity in the receiving space and on the curved intersecting region, wherein the first circuits are each electrically coupled with a component received in the receiving space; and
a plurality of packaging holder disposed on the plurality of ledges, each packaging holder having a component on a surface thereof.

30. The pre-molded cavity 3D packaging module with layout of claim 29, wherein the cavity bottom at the curved intersecting region forms steps of different heights to facilitate staggered wire layouts or wire bonding on different vertical planes.

31. The pre-molded cavity 3D packaging module with layout of claim 29, wherein the packaging cavity includes a plurality of first vias through which the first circuits are electrically coupled to external circuits.

32. The pre-molded cavity 3D packaging module with layout of claim 31, wherein the outer surface of the packaging cavity includes a plurality of signal transmitting regions, which transmit incoming/outgoing signals to/from the first circuits through the first vias.

33. The pre-molded cavity 3D packaging module with layout of claim 32, wherein the signal transmitting regions are module testing regions.

34. The pre-molded cavity 3D packaging module with layout of claim 29, wherein the plurality of packaging holders include a plurality of second vias and second circuits with specific layouts, the second circuits are formed on surfaces of the plurality of packaging holders, and electrically coupled with components on both surfaces of the packaging holders through the plurality of second vias.

35. The pre-molded cavity 3D packaging module with layout of claim 29, wherein the packaging cavity includes at least one heat-dissipating path, wherein the at least one heat-dissipating path has at least one heat-dissipating area exposed from the outer surface of the packaging cavity.

36. The pre-molded cavity 3D packaging module with layout of claim 29, wherein the packaging cavity includes at least one air hole for exchanging air with an external environment to form an air-type packaging module, wherein a material is filled into the air hole to block the air hole, and during assembly of the packaging cavity, inert gas is filled into it, or it is heated to remove moisture to form a sealed packaging module.

37. The pre-molded cavity 3D packaging module with layout of claim 29, wherein the receiving space of the packaging cavity is filled with a liquid material with low stress for protecting internal components and solder wires.

38. A pre-molded cavity three-dimensional (3D) packaging module with layout, comprising:
a plurality of packaging cavities, each forming a receiving space by a cavity bottom and a cavity sidewall surrounding the cavity sidewall, wherein the cavity sidewall forms an inclined angle greater than 3° with a vertical axis of the cavity bottom, and an intersecting region between the cavity sidewall and the cavity bottom is a curved intersecting region;
the plurality of packaging cavities further including a first packaging cavity, a second packaging cavity, a third packaging cavity, and a fourth packaging cavity, wherein the second packaging cavity and the third packaging cavity are matching in appearance and symmetrical with each other, and with opening larger than the cavity sidewall of the first packaging cavity to be assembled to the cavity sidewall, and the cavity sidewall of the first packaging cavity has a plurality of steps forming staircase-like surface with a plurality of ledges in the receiving space;
a plurality of first circuits with specific layouts formed on a surface of a packaging cavity in the receiving space and on the curved intersecting region, wherein the first circuits are each electrically coupled with a component received in the receiving space; and
a plurality of packaging holder disposed on the plurality of ledges, each packaging holder having a component on a surface thereof.

39. The pre-molded cavity 3D packaging module with layout of claim 38, wherein the cavity bottom at the curved intersecting region forms steps of different heights to facilitate staggered wire layouts or wire bonding on different vertical planes.

40. The pre-molded cavity 3D packaging module with layout of claim 38, wherein the plurality of packaging cavities include a plurality of first vias through which the first circuits are electrically coupled to external circuits.

41. The pre-molded cavity 3D packaging module with layout of claim 40, wherein the outer surfaces of the plurality of packaging cavities include a plurality of signal transmitting regions, which transmit incoming/outgoing signals to/from the first circuits through the first vias.

42. The pre-molded cavity 3D packaging module with layout of claim 41, wherein the signal transmitting regions are module testing regions.

43. The pre-molded cavity 3D packaging module with layout of claim 38, wherein the plurality of packaging holders include a plurality of second vias and second circuits with specific layouts, the second circuits are formed on surfaces of the plurality of packaging holders, and electrically coupled with components on both surfaces of the packaging holders through the plurality of second vias.

44. The pre-molded cavity 3D packaging module with layout of claim 38, wherein the packaging cavities each includes at least one heat-dissipating path, wherein the at least one heat-dissipating path has at least one heat-dissipating area exposed from the outer surface of the packaging cavity.

45. The pre-molded cavity 3D packaging module with layout of claim 38, wherein the packaging cavities each includes at least one air hole for exchanging air with an external environment to form an air-type packaging module, wherein a material is filled into the air hole to block the air hole, and during assembly of the packaging cavity, inert gas is filled into it, or it is heated to remove moisture to form a sealed packaging module.

46. The pre-molded cavity 3D packaging module with layout of claim 38, wherein the receiving space of each packaging cavity is filled with a liquid material with low stress for protecting internal components and solder wires.
